(19) United States
(12) Patent Application Publication
(10) Pub. No.: US 2011/0061900 A1
(43) Pub. Date: Mar. 17, 2011

(54) Wired-circuit-board assembly sheet and producing method thereof

(75) Inventors: Shigehiro Umetani, Osaka (JP); Yoshihiko Kondou, Osaka (JP); Hiroyuki Tanabe, Osaka (JP)

(73) Assignee: Nitto Denko Corporation, Osaka (JP)

(21) Appl. No.: 12/923,159

(22) Filed: Sep. 7, 2010

Related U.S. Application Data
(60) Provisional application No. 61/272,455, filed on Sep. 25, 2009.

(30) Foreign Application Priority Data
Sep. 16, 2009 (JP) 2009-214764

(51) Int. Cl. H05K 1/00; H05K 3/02

(52) U.S. Cl. 174/250; 29/847

(57) ABSTRACT

A wired-circuit-board-assembly sheet includes a plurality of wired circuit boards arranged in parallel in one direction, which are regularly omitted at given intervals, and a plurality of units defined by margin portions where the wired circuit boards are omitted.

The present application claims the benefit of U.S. Provisional Application No. 61/272,455 filed on Sep. 25, 2009, and claims priority from Japanese Patent Application No. 2009-214764 filed on Sep. 16, 2009, the contents of which are herein incorporated by reference into this application.

### BACKGROUND OF THE INVENTION

1. Field of the Invention

The present invention relates to a wired-circuit-board assembly sheet and a producing method thereof and, more particularly, to a wired-circuit-board assembly sheet used appropriately as a suspension-board-with-circuit assembly sheet and a producing method thereof.

2. Description of the Related Art

There has been conventionally known a suspension-board-with-circuit assembly sheet including a plurality of suspension boards with circuit which are arranged in an aligned state. The suspension-board-with-circuit assembly sheet is obtained by laminating an insulating base layer, a conductive layer, and the like on a metal sheet, and then trimming the metal sheet correspondingly to the suspension boards with circuit.

In such a suspension-board-with-circuit assembly sheet, the metal sheet except for the portions thereof corresponding to the suspension boards with circuit is not provided as the products of the suspension boards with circuit, which results in a material loss. Therefore, it has been requested to reduce such a material loss.

For example, it has been proposed that, while a lengthwise member to be worked is transported, suspension boards in each of which an insulating layer and a wiring pattern are successively laminated on a metal board are trimmed into juxtaposed shapes parallel with a lengthwise direction to reduce a material loss resulting from the dimensional (size) difference between the individual suspension boards (see, e.g., Japanese Unexamined Patent No. 2008-305492).

Also, in Japanese Unexamined Patent No. 2008-305492, product frames (units) are provided in each of which the plurality of suspension boards are arranged in parallel with each other in a direction perpendicular to the lengthwise direction. The individual product frames are arranged in parallel to be spaced apart from each other in the lengthwise direction.

### SUMMARY OF THE INVENTION

However, in the member to be worked of Japanese Unexamined Patent No. 2008-305492, the distances (spacings) between the product frames which are adjacent in the lengthwise direction are not strictly set and, consequently, a material loss between the product frames in the member to be worked may increase.

It is therefore an object of the present invention to provide a wired-circuit-board assembly sheet which allows an improvement in production yield as well as a reduction in production cost with a simple structure, and a producing method thereof.

A wired-circuit-board assembly of the present invention includes a plurality of wired circuit boards arranged in parallel in one direction, the wired circuit boards being regularly omitted at given intervals, and a plurality of units defined by margin portions where the wired circuit boards are omitted.

In the wired-circuit-board assembly sheet, the margin portions each having a specified shape are provided. Accordingly, even when the wired circuit boards each having a specified shape are arranged at a high density, i.e., arranged with minimized spacings, the production yield can be improved.

Additionally, the margin portions are provided easily and uniformly, and therefore the units are defined easily and uniformly.

As a result, the wired-circuit-board assembly sheet can be obtained as a wired-circuit-board assembly sheet in which the production yield is improved, and the production cost is reduced easily and uniformly.

In the wired-circuit-board assembly sheet of the present invention, it is preferable that each of the wired circuit boards has a bent portion which is bent in the one direction.

When the wired circuit board merely has the bent portion, a space resulting from the bent portion is likely to be formed in each of the margin portions. In that case, the production yield decreases to increase the production cost.

However, in the wired-circuit-board assembly sheet of the present invention, the margin portions correspond to portions where the wired circuit boards are omitted so that such margin portions are also bent correspondingly to the bent portions of the wired circuit boards. Therefore, it is possible to form each of the wired circuit boards into a complicated shape, and prevent the formation of the space mentioned above in the margin portion. This achieves an improvement in production yield, and allows a reduction in production cost.

In the wired-circuit-board assembly sheet of the present invention, it is preferable that the wired circuit boards are arranged in parallel such that respective longitudinal directions thereof cross the one direction, and each of the margin portions is continuous in the longitudinal directions, and it is also preferable that each of the margin portions is formed with a slit extending along the longitudinal directions.

When the wired circuit boards are arranged in parallel such that the respective longitudinal directions thereof extend along the one direction, it is necessary to provide each of the margin portions corresponding to the respective longitudinal lengths of the omitted wired circuit boards with a relatively large area.

However, in the wired-circuit-board assembly sheet of the present invention, the wired circuit boards are arranged in parallel along directions in which the respective longitudinal directions thereof cross the one direction. Accordingly, it is possible to provide each of the margin portions corresponding to the respective lengths of the omitted wired circuit boards in the crossing directions with a relatively small area. This allows a further improvement in production yield.

Moreover, since each of the margin portions is continuous, a simple structure can be implemented.

This allows an easier reduction in production cost.

In addition, by separating the units along the slit, the units can be easily obtained.

In the wired-circuit-board assembly sheet of the present invention, it is preferable that the wired circuit-board assembly sheet is formed into a lengthwise shape, and the individual units are arranged in parallel along a lengthwise direction of the wired-circuit-board assembly sheet.

If the wired-circuit-board assembly sheet is transported along the lengthwise direction, a wired-circuit-board-assembly sheet with improved production efficiency can be obtained.

A producing method of the wired-circuit-board assembly sheet of the present invention includes the steps of forming a plurality of wired circuit boards such that the wired circuit boards are arranged in parallel in one direction, and forming a plurality of units such that the wired circuit boards are regularly omitted at given intervals, and the units are defined by margin portions where the wired circuit boards are omitted.

In accordance with the producing method, the margin portions each having a specified shape are provided. Accordingly, even when the wired circuit boards each having a specified shape are arranged at a high density, i.e., arranged with minimized spacings, the production yield can be improved.

Additionally, the margin portions can be provided easily and uniformly, and therefore the units can be defined easily and uniformly.

As a result, it is possible to achieve an improvement in production yield, and allow an easy and uniform reduction in production cost.

In the producing method of the wired-circuit-board assembly sheet of the present invention, it is preferable that, in the step of forming the wired circuit boards, each of the wired circuit boards is formed to have a bent portion which is bent in the one direction.

When the wired circuit board has the bent portion, a space resulting from the bent portion is likely to be formed in each of the margin portions. In that case, the production yield decreases to increase the production cost.

However, in the producing method of the present invention, the margin portions correspond to portions where the wired circuit boards are omitted so that such margin portions are also formed to be bent correspondingly to the bent portions of the wired circuit boards. Therefore, it is possible to form each of the wired circuit boards into a complicated shape, and prevent the formation of the space mentioned above in the margin portion. This achieves an improvement in production yield, and allows a reduction in production cost.

In the producing method of the wired-circuit-board assembly sheet of the present invention, it is preferable that, in the step of forming the wired circuit boards, a metal layer made of a metal sheet, an insulating layer to be formed thereon, and a conductive layer to be formed thereon are formed, and the step of forming the units includes the step of forming a photoresist on one side of the metal sheet in a thickness direction thereof, a first exposure step of placing a photomask on one side of a portion of the photoresist corresponding to a given one of the plurality of units in a thickness direction thereof, and exposing the portion of the photoresist to light via the photomask, a second exposure step of placing the photomask on the one side of a portion of the photoresist corresponding to the adjacent unit that is adjacent to the given unit in the thickness direction thereof, and exposing the portion of the photoresist to light via the photomask, the step of removing an unexposed portion of the photoresist after the first exposure step and the second exposure step by development to form an etching resist, and an etching step of etching the metal sheet exposed from the etching resist.

In the producing method of the present invention, the common photomask is placed in succession on the one side of the portion of the photoresist corresponding the one unit in the thickness direction thereof and on the one side of the portion of the photoresist corresponding to the adjacent unit in the thickness direction thereof in the first exposure step and in the second exposure step, and the portions of the photoresist are exposed to light in succession via the same photomask. Therefore, it is possible to easily perform each of the exposure steps, and easily form an etching resist corresponding to the given unit and the adjacent unit. As a result, the production cost can be reduced.

In the producing method of the wired-circuit-board assembly sheet of the present invention, it is preferable that, in the step of forming the wired circuit boards, the wired circuit boards are formed such that respective longitudinal directions thereof cross the one direction, and, in the etching step, each of the margin portions is formed to be continuous in the longitudinal directions, and it is also preferable that, in the etching step, a slit is formed in each of the margin portions so as to extend along the longitudinal directions.

When the wired circuit boards are formed such that the respective longitudinal directions thereof extend along the one direction, it is necessary to provide each of the margin portions corresponding to the respective longitudinal lengths of the omitted wired circuit boards with a relatively large area.

However, in the producing method, the wired circuit boards are formed such that the respective longitudinal directions of the wired circuit boards cross the one direction. Accordingly, it is possible to provide each of the margin portions corresponding to the respective lengths of the omitted wired circuit boards in the crossing directions with a relatively small area. This allows a further improvement in production yield.

Moreover, since the margin portions are formed to be continuous, the margin portions can be formed easily.

This allows an easier reduction in production cost.

In addition, by separating the units along the slit, the units can be easily obtained. This allows a further reduction in production cost.

In the producing method of the present invention, it is preferable that, in the step of forming the wired circuit boards, the metal sheet having a lengthwise shape is used, and, in the step of forming the units, the units are formed so as to be arranged in parallel along a lengthwise direction of the metal sheet.

In the producing method, the units can be efficiently formed, while the suspension-board-with-circuit assembly sheet is transported along the lengthwise direction. Therefore, the production efficiency can be improved.

### BRIEF DESCRIPTION OF THE DRAWINGS

FIG. 1 is a plan view of a suspension-board-with-circuit assembly sheet which is an embodiment of a wired-circuit-board assembly sheet of the present invention;

FIG. 2 is an enlarged view of the margin portion of the suspension-board-with-circuit assembly sheet shown in FIG. 1;

FIG. 3 is a plan view of each of the suspension boards with circuit of the suspension-board-with-circuit assembly sheet shown in FIGS. 1 and 2;

FIG. 4 is a cross-sectional view of the suspension board with circuit along the line A-A of FIG. 3;

FIG. 5 is a production process view for illustrating a producing method of the suspension-board-with-circuit assembly sheet shown in FIG. 2, which is a cross-sectional view along the line B-B of FIG. 2,

(a) showing the step of forming an insulating base layer on a metal sheet,

(b) showing the step of forming a first etching resist and a second photoresist over and under the metal sheet,

(c) showing the step of placing a photomask under the portion of the second photoresist corresponding to a given unit under the metal sheet, and exposing the portion of the second photoresist to light via the photomask,

(d) showing the step of placing the photomask under the portion the second photoresist corresponding to an adjacent unit under the metal sheet, and exposing the portion of the second photoresist to light via the photomask,

(e) showing the step of developing and curing the second photoresist to form a second etching resist,

(f) etching the metal sheet, and

(g) removing the second etching resist; and

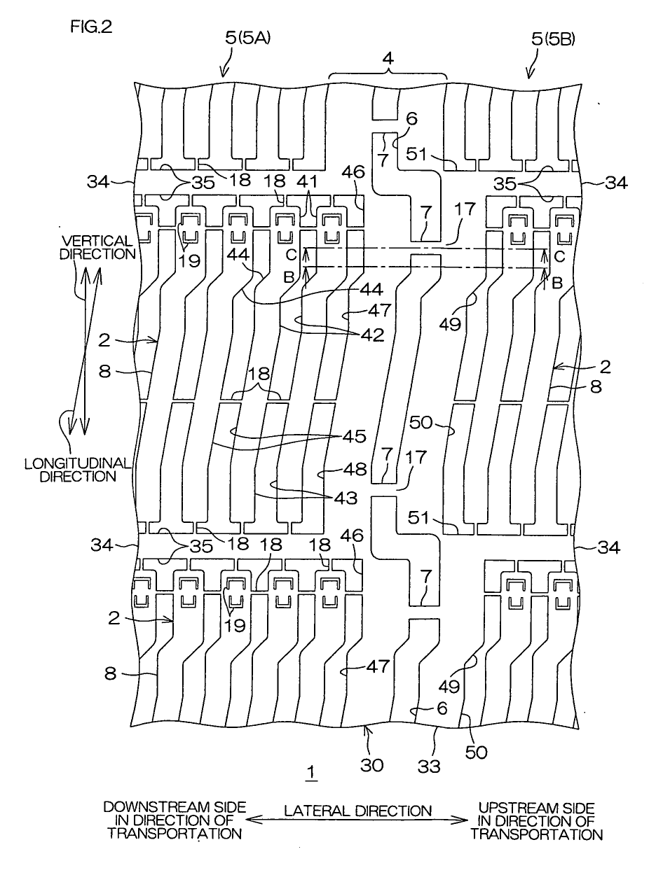

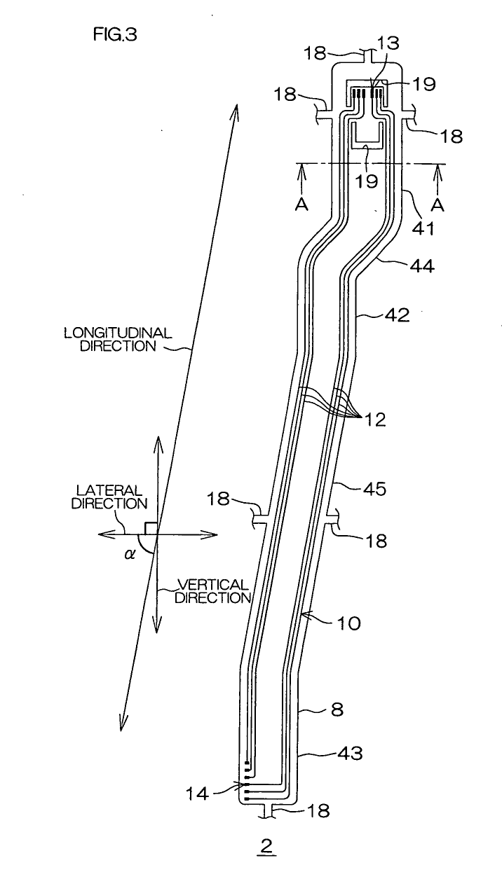

FIG. 6 is a production process view for illustrating the producing method of the suspension-board-with-circuit assembly sheet shown in FIG. 2, which is a cross-sectional view along the line C-C of FIG. 2,

(a) showing the step of forming the insulating base layer on the metal sheet,

(b) showing the step of forming the first etching resist and the second photoresist over and under the metal sheet,

(c) showing the step of placing the photomask under the portion of the second photoresist corresponding to the given unit under the metal sheet, and exposing the portion of the second photoresist to light via the photomask,

(d) showing the step of placing the photomask under the portion of the second photoresist corresponding to the adjacent unit under the metal sheet, and exposing the portion of the second photoresist to light via the photomask,

(e) showing the step of developing and curing the second photoresist to form the second etching resist,

(f) showing the step of etching the metal sheet, and

(g) showing the step of removing the second etching resist.

### DETAILED DESCRIPTION OF THE INVENTION

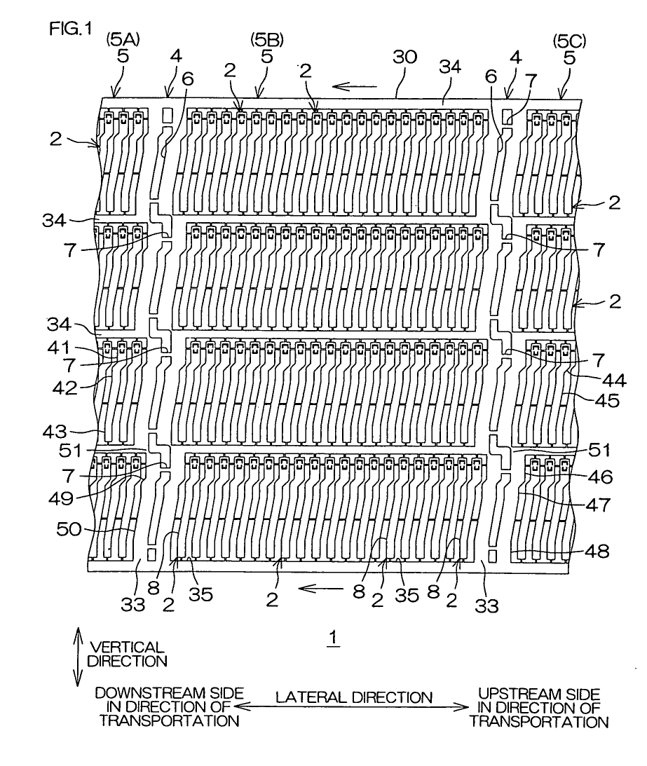

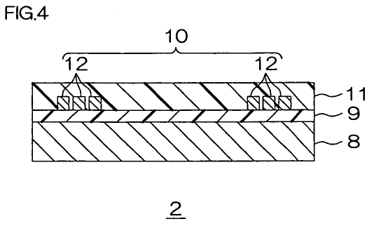

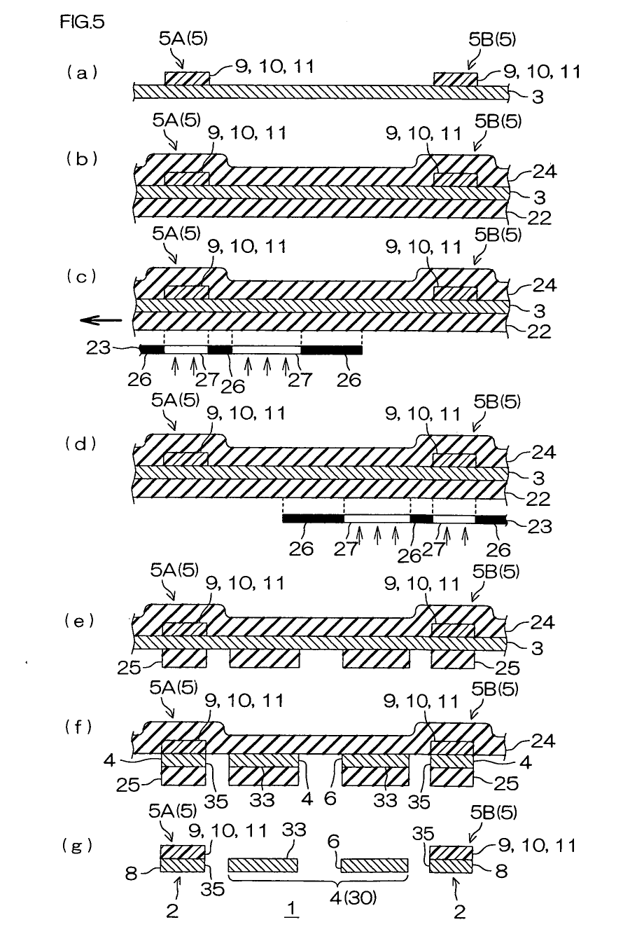

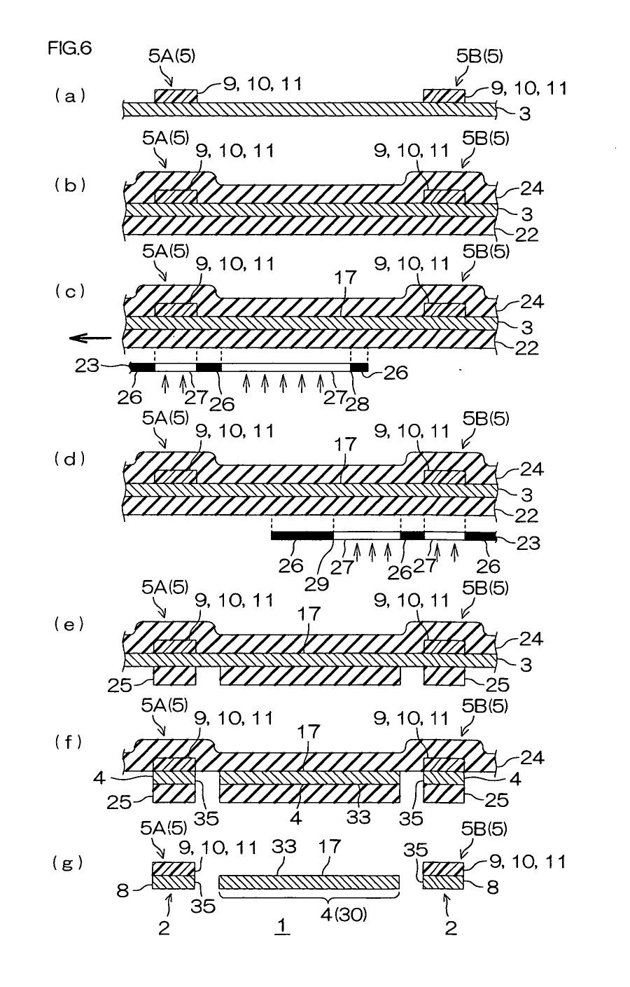

FIG. 1 is a plan view of a suspension-board-with-circuit assembly sheet which is an embodiment of a wired-circuit-board assembly sheet of the present invention. FIG. 2 is a principal-portion enlarged view of the margin portion of the suspension-board-with-circuit assembly sheet shown in FIG. 1. FIG. 3 is a plan view of each of the suspension boards with circuit of the suspension-board-with-circuit assembly sheet shown in FIGS. 1 and 2. FIG. 4 is a cross-sectional view of the suspension board with circuit along the line A-A of FIG. 3. FIGS. 5 and 6 are production process views for illustrating a producing method of the suspension-board-with-circuit assembly sheet shown in FIG. 2, which are cross-sectional views along the respective lines B-B and C-C of FIG. 2.

Note that, for clear illustration of relative positioning of a metal layer 8, an insulating base layer 9 and an insulating cover layer 11, each described later, are omitted in FIGS. 1 to 3, and a conductive layer 10 is omitted in FIGS. 1 and 2.

In FIG. 1, a suspension-board-with-circuit assembly sheet 1 can be obtained by successively forming the insulating base layer 9, the conductive layer 10, and the insulating cover layer 11 (see FIG. 4), each described later, on a metal sheet 3 (see FIGS. 5 and 6) having a lengthwise shape extending long in one direction (the direction of transportation in a roll-to-roll method or the lateral direction in FIG. 1, which may be hereinafter simply referred to as the lateral direction) by the roll-to-roll method, and then trimming the metal sheet 3.

The suspension-board-with-circuit assembly sheet 1 is formed into a lengthwise shape extending in the lateral direction, and includes a support frame 30 formed from the metal sheet 3 (see FIGS. 5 and 6) to have a lengthwise shape extending in the lateral direction, and suspension boards with circuit 2 as a plurality of wired circuit boards which are separably supported by the support frame 30, and arranged in an aligned state.

The support frame 30 is formed of vertical frames 33 and lateral frames 34 to have an elongated frame shape surrounding each of the suspension boards with circuit 2.

The plurality of (numerous) vertical frames 33 extend in a vertical direction (direction perpendicular to the direction of transportation or the vertical direction in FIG. 1), and are arranged in laterally spaced-apart relation.

The plurality of (five) lateral frames 34 extend in the lateral direction so as to connect the vertical frames 33 opposing each other in the lateral direction, and are arranged in vertically spaced-apart relation.

In the support frame 30, the vertical frames 33 are provided as margin portions 4 described later. The margin portions 4 define units 5 each including a predetermined number of the suspension boards with circuit 2.

The plurality of units 5 are arranged in parallel along the lateral direction.

In the support frame 30, the suspension boards with circuit 2 are arranged in parallel in each of the lateral direction and the vertical direction. More specifically, the suspension boards with circuit 2 are arranged vertically in four rows and laterally in numerous columns. The suspension boards with circuit 2 are also regularly omitted at given lateral intervals, as described later in detail.

In each of the units 5, the suspension boards with circuit 2 are arranged densely (at a high density) in parallel in each of the lateral direction and the vertical direction. More specifically, the suspension boards with circuit 2 are arranged vertically in the four rows and laterally in twenty columns.

As shown in FIGS. 2 and 3, each of the suspension boards with circuit 2 is formed in a generally flat-belt shape extending in the longitudinal direction thereof (direction along a line segment connecting a lateral center in the front end thereof and a lateral center in the rear end thereof, each described later). The longitudinal direction of the suspension board with circuit 2 crosses the lateral direction, and also crosses the vertical direction. That is, the longitudinal direction of the suspension board with circuit 2 is slightly inclined with respect to the vertical direction. The angle α formed between the longitudinal direction of the suspension board with circuit 2 and the lateral direction is in a range of, e.g., 45 to 89°, or preferably 60 to 85°.

Therefore, as shown in FIG. 2, the rear end portion of each of the suspension boards with circuit 2 arranged in parallel in the vertical direction and the front end portion of the other suspension board with circuit 2 disposed on the rear side of the suspension board with circuit 2 are displaced in the lateral direction when projected in the vertical direction.

As shown in FIG. 4, the suspension board with circuit 2 includes the metal layer 8, the insulating base layer 9 as an insulating layer formed on the metal layer 8, the conductive layer 10 formed on the insulating base layer 9, and the insulating cover layer 11 formed on the insulating base layer 9 so as to cover the conductive layer 10.

As shown in FIGS. 1 and 5, the metal layer 8 is formed from the metal sheet 3 together with the support frame 30 to have a shape corresponding to the outer shape of the suspension board with circuit 2. As shown in FIGS. 2 and 3, the metal layer 8 integrally includes a first linear portion 41, a second linear portion 42, a third linear portion 43, and also includes a first bent portion 44 and a second bent portion 45 each as a bent portion.

Each of the first linear portion 41, the second linear portion 42, and the third linear portion 43 is formed to linearly extend along the vertical direction, and have generally the same width (lateral length). The first linear portion 41, the second linear portion 42, and the third linear portion 43 are positioned respectively in the front end portion of the metal layer 8, the middle portion (midway portion between the front end portion and the rear end portion) thereof, and the rear end portion thereof.

Each of the first bent portion 44 and the second bent portion 45 is formed to be bent in the lateral direction. Specifically, the first bent portion 44 is formed between the first linear portion 41 and the second linear portion 42 to be continued thereto, inclinedly bent from the front end of the second linear portion 42 toward one side in the lateral direction (the upstream side in the direction of transportation or the right side), and then reach the rear end of the first linear portion 41.

The second bent portion 45 is formed between the second linear portion 42 and the third linear portion 43 to be continued thereto, inclinedly bent from the rear end of the second linear portion 42 toward the other side in the lateral direction (the downstream side in the direction of transportation or the left side), and then reach the rear end of the third linear portion 43.

Each of the first bent portion 44 and the second bent portion 45 is formed to have generally the same width, which is also generally the same as the width of each of the first linear portion 41, the second linear portion 42, and the third linear portion 43.

As shown in FIG. 3, the metal layer 8 is formed with a second slit 19 extending through the metal layer 8 in the thickness direction thereof. The second slit 19 is opened in a generally U-shaped plan view shape in which head-side terminals 13 (described later) are interposed in the vertically direction.

As shown in FIG. 2, gap grooves 35 are formed around the metal layer 8. The gap grooves 35 are opened by trimming the metal sheet 3 described above.

The metal layer 8 is also connected to second joint portions 18.

The plurality of second joint portions 18 are spacedly arranged in the peripheral direction of the metal layer 8. Each of the second joint portions 18 is formed in a generally elongated rectangular plan view shape extending from the peripheral end of the metal layer 8 toward the outside (inner end of the support frame 30), and traversing the gap groove 35 to be connected to the support frame 30. The second joint portions 18 are separably formed, and support the metal layer 8 with respect to the support frame 30.

Examples of a metal used to form the metal sheet 3 including the metal layer 8 and the second joint portions 18 include stainless steel and a 42-alloy. Preferably, stainless steel is used. The thickness of the metal sheet 3 is in a range of, e.g., 10 to 100 μm, or preferably 18 to 30 μm.

As shown in FIG. 4, the insulating base layer 9 is formed on the upper surface of the metal layer 8 into a pattern corresponding to a portion where the conductive layer 10 is formed. Examples of an insulating material used to form the insulating base layer 9 include synthetic resins such as polyimide, acryl, polyether nitrile, polyether sulfone, polyethylene terephthalate, polyethylene naphthalate, and polyvinyl chloride. Among them, a photosensitive synthetic resin is preferably used or, more preferably, photosensitive polyimide is used. The thickness of the insulating base layer 9 is in a range of, e.g., 3 to 30 μm, or preferably 5 to 15 μm.

As shown in FIG. 3, the conductive layer 10 integrally includes a plurality of wires 12 arranged in parallel and mutually spaced-apart relation, the head-side terminals 13 continued to each of the front end portions and rear end portions of the wires 12, and external terminals 14.

Examples of a conductive material used to form the conductive layer 10 include a metal foil of copper, nickel, gold, a solder, an alloy thereof, or the like. Preferably, a copper foil is used. Te thickness of the conductive layer 10 is in a range of, e.g., 3 to 20 μm, or preferably 7 to 15 μm. The width of each of the wires 12 is in a range of, e.g., 5 to 500 μm, or preferably 10 to 200 μm. The spacing between the individual wires 12 is in a range of, e.g., 5 to 500 μm, or preferably 10 to 200 μm.

As shown in FIG. 4, the insulating cover layer 11 is formed on the insulating base layer 9 into a pattern covering the wires 12, and exposing the head-side terminals 13 and the external terminals 14. As an insulating material for forming the insulating cover layer 11, the same insulating material as that used to form the insulating base layer 9 shown above is used. Preferably, photosensitive polyimide is used. The thickness of the insulating cover layer 11 is in a range of, e.g., 3 to 20 μm, or preferably 4 to 15 μm.

As shown in FIGS. 1 and 2, the suspension-board-with-circuit assembly sheet 1 is provided with the margin portions 4 where the suspension boards with circuit 2 are regularly omitted at given lateral intervals.

The margin portions 4 are provided as portions where the suspension boards with circuit 2 laterally arranged in parallel are regularly omitted at given intervals (one of every twenty suspension boards with circuit 2 laterally arranged in parallel is omitted in FIG. 1), and the formation of the suspension boards with circuit 2 (three suspension boards with circuit 2 in FIG. 1) is skipped. Specifically, the margin portions 4 are formed so as to correspond to the outer shapes of the omitted (skipped) suspension boards with circuit 2 (suspension boards with circuit 2 arranged vertically in the four rows and laterally in the three columns).

The margin portions 4 are formed as the vertical frames 33, and are each formed in vertically continuous relation. More specifically, each of the margin portions 4 is continuous along the respective longitudinal directions of the individual suspension boards with circuit 2, and is formed in a zig-zag (generally Z-shaped or generally indented) plan view shape extending in the vertical direction. In greater detail, each of the margin portions 4 integrally includes fourth linear portions 46, fifth linear portions 47, and six linear portions 48 which are formed to correspond to the first linear portions 41, the second linear portions 42, and the third linear portions 43, respectively, and also includes third bent portions 49 and fourth bent portions 50 which are formed to correspond to the first bent portions 44 and the second bent portions 45, respectively.

The margin portion 4 further includes fifth bent portions 51 each formed in a generally stepped (generally L-shaped) plan view shape to connect the rear end portion of the sixth linear portion 48 corresponding to the third linear portion 43 of one of the suspension boards with circuit 2 and the front end portion of the fourth linear portion 46 corresponding to the first linear portion 41 of the suspension board with circuit 2 disposed on the rear side of the suspension board with circuit 2 mentioned above. That is, each of the margin portions 4 is continuous in the vertical direction such that the fourth linear portions 46, the third bent portions 49, the fifth linear portions 47, the fourth bent portions 50, the sixth linear portions 48, and the fifth bent portions 51 are vertically and repeatedly arranged in this order in succession.

In the lateral center of each of the margin portions 4, a first slit 6 is formed as a slit extending therethrough in the thickness direction.

The first slit 6 is formed correspondingly to and smaller in width than the outer shape of the margin portion 4. The first slit 6 is formed continuous along the respective longitudinal directions of the individual suspension boards with circuit 2 so as to separate the units 5 on both lateral sides of the slit 6. The first slit 6 is opened in a zig-zag plan view (generally Z-shaped or indented) shape which is continuous along the respective longitudinal directions of the individual suspension boards with circuit 2.

The margin portions 4 are also provided with first joint portions 7.

The plurality of first joint portions 7 are arranged in longitudinally spaced-apart relation, and formed to traverse the slit 6. Each of the first joint portions 7 is separably formed in a generally elongated rectangular plan view shape to connect and support the units 5 that are adjacent to each other in the lateral direction.

Next, a producing method of the suspension-board-with-circuit assembly sheet 1 is described with reference to FIGS. 5 and 6.

In the method, as shown in FIG. 5(a), the lengthwise metal sheet 3 is prepared first. Then, the insulating base layer 9, the conductive layer 10, and the insulating cover layer 11 are successively formed on the metal sheet 3.

That is, as shown in FIG. 4, the insulating base layer 9 is formed in the foregoing pattern by coating a solution (varnish) of a photosensitive synthetic resin on the entire upper surface of the metal sheet 3, drying the resultant coating, exposing the coating to light, developing the coating, and then curing the coating by heating as necessary.

The conductive layer 10 is formed on the insulating base layer 9 by a known patterning method such as an additive method or a subtractive method.

The insulating cover layer 11 is formed in the foregoing pattern on the insulating base layer 9 by coating a solution (varnish) of a photosensitive synthetic resin on the entire upper surfaces of the metal sheet 3, the insulating base layer 9, and the conductive layer 10, drying the resultant coating, exposing the coating to light, developing the coating, and then curing the coating by heating as necessary. Note that the insulating cover layer 11 is formed so as to expose the head-side terminals 13 and the external terminals 14 (see FIG. 3).

The insulating base layer 9, the conductive layer 10, and the insulating cover layer 11 are each formed so as to expose at least the upper surfaces of the margin portions 4.

Next, as shown in FIGS. 5(b) to 5(g) and 6(b) to 6(g), the first slits 6, the gap grooves 35, and the second slits 19 (see FIG. 3) are formed to simultaneously form the suspension boards with circuit 2 and the units 5 including the suspension boards with circuit 2.

To form the first slits 6, the gap grooves 35, and the second slits 19, a first etching resist 24 and a second etching resist 25 as an etching resist are formed respectively on the upper surface and lower surface of the metal sheet 3, as shown in FIGS. 5(b) to 5(e) and 6(b) to 6(e).

That is, to form the first etching resist 24, a dry film resist or the like is formed on the entire upper surface of the metal sheet 3 including the insulating base layer 9, the conductive layer 10, and the insulating cover layer 11, as shown in FIGS. 5(b) and 6(b).

To form the second etching resist 25, a second photoresist 22 as a photoresist is formed on the entire lower surface of the metal sheet 3, as shown in FIGS. 5(b) and 6(b).

Next, as shown in FIGS. 5(c) and 6(c), a photomask 23 is placed under the portion of the second photoresist 22 corresponding to a given one 5A (see FIGS. 1 and 2) of the plurality of units 5, and the portion of the second photoresist 22 corresponding to the given unit 5A is exposed to light from therebelow via the photomask 23 (first exposure step).

In the photomask 23, a pattern for forming the metal layer 8 and the support frame 30 each corresponding to the given unit 5A is formed. Specifically, the photomask 23 is formed in the pattern including light shielding portions 26 which do not transmit light and light transmitting portions 27 which transmit light to have a lateral length corresponding to (slightly larger than) that of the given unit 5A.

Then, the photomask 23 is placed such that the light transmitting portions 27 oppose the portions where the metal layer 8 and the support frame 30 are to be formed and the light shielding portions 26 oppose the portions where the metal layer 8 and the support frame 30 are not to be formed (i.e., the portions where the second slits 19 (see FIG. 3), the gap grooves 35, and the first slits 6 are to be formed).

Subsequently, the portion of the second photoresist 22 corresponding to the given unit 5A is exposed to light from therebelow via the photomask 23.

As a result, of the portion of the second photoresist 22 corresponding to the given unit 5A, the portions opposing the light shielding portions 26 become unexposed portions, and the portions opposing the light transmitting portions 27 become exposed portions.

Then, as shown in FIGS. 5(d) and 6(d), the photomask 23 described above is placed under the portion of the second photoresist 22 corresponding to an adjacent unit 5B which is adjacent to the given unit 5A on the right side (upstream side in the direction of transportation) thereof, and the portion of the second photoresist 22 corresponding to the adjacent unit 5B is exposed to light from therebelow via the photomask 23 (second exposure step).

To move the photomask 23 from under the portion of the second photoresist 22 corresponding to the given unit 5A to a position under the portion of the second photoresist 22 corresponding to the adjacent unit 5B, the photomask 23 is moved relative to the second photoresist 22. To move the photomask 23 relative to the second photoresist 22, the metal sheet 3 formed with the second photoresist 22 is transported toward the downstream side in the direction of transportation by a distance corresponding to the longitudinal length of one of the units 5, while the photomask 23 is kept in a fixed state, as indicated by, e.g., the bold arrows of FIGS. 5(c) and 6(c).

Subsequently, the portion of the second photoresist 22 corresponding to the adjacent unit 5B is exposed to light from therebelow via the photomask 23 (second exposure step).

As a result, of the portion of the second photoresist 22 corresponding to the adjacent unit 5B, the portions opposing the light shielding portions 26 become unexposed portions, and the portions opposing the light transmitting portions 27 become exposed portions.

Note that, as shown in FIGS. 6(c) and 6(d), the light transmitting portions 27 are disposed in opposing relation such that, in the right-hand half of the margin portion 4 (see FIG. 2), the portion of the second photoresist 22 corresponding to a right-hand portion 17 located on the right side of the right end of each of the first joint portions 7 becomes an exposed portion in each of the first exposure step and the second exposure step. That is, by disposing a left end edge 29 (see FIG. 6(d)) of the light transmitting portions 27 of the photomask 23 in the second exposure step on the left side of a right end edge 28 (see FIG. 6(c)) of the light transmitting portions 27 of the photomask 23 in the first exposure step, the portion of the second photoresist 22 corresponding to the right-hand portion 17 is doubly exposed (exposed twice) to light.

Then, the photomask 23 is placed under the portion of the second photoresist 22 corresponding to a unit 5C (see FIG. 1) which is adjacent to the adjacent unit 5B on the right side (upstream side in the direction of transportation) thereof, and the portion of the second photoresist 22 corresponding to the unit 5C is exposed to light from therebelow via the photomask 23. Thereafter, the operation described above is similarly repeated. In this manner, the respective portions of the second photoresist 22 corresponding to all the units 5 are each exposed to light.

Then, as shown in FIGS. 5(e) and 6(e), the unexposed portions of the second photoresist 22 after the exposure steps (all the exposure steps including the first exposure step and the second exposure step) are removed by development. For the development, a dipping method, a spray method, or the like, e.g., is used.

Thereafter, the second photoresist 22 is cured by heating as necessary to form the second etching resist 25.

The second etching resist 25 is formed in a pattern covering the portions of the lower surface of the metal sheet 3 where the metal layer 8 and the support frame 30 are to be formed, and exposing the portions thereof where the second slits 19 (see FIG. 3), the gap grooves 35, and the first slits 6 are to be formed.

Note that the first etching resist 24 can be formed by forming a photoresist made of the same material as that of the second photoresist 22 on the entire upper surface of the metal sheet 3 including the insulating base layer 9, the conductive layer 10, and the insulating cover layer 11, and curing the photoresist by heating together with the second photoresist 22 without exposing the photoresist to light and developing the photoresist.

Then, as shown in FIGS. 5(f) and 6(f), the metal sheet 3 exposed from the second etching resist 25 is etched (etching step).

For the etching, a dipping method, a spray method, or the like using an etchant such as, e.g., an aqueous ferric chloride solution is used.

Then, as shown in FIGS. 5(g) and 6(g), the first etching resist 24 and the second etching resist 25 are removed by, e.g., stripping, etching, or the like.

In this manner, the suspension boards with circuit 2 arranged in parallel in each the lateral direction and the vertical direction, and the units 5 defined by the margin portions 4 where the suspension boards with circuit 2 are omitted are simultaneously formed.

In accordance with the method, even when the suspension boards with circuit 2 each having a specified shape are arranged at a high density, i.e., arranged with minimum lateral spacings, the production yield can be improved since the margin portions 4 each having the specified shape described above are provided.

In addition, since the margin portions 4 can be provided easily and uniformly, the units 5 can be defined easily and uniformly.

As a result, it is possible to improve the production yield, and easily and uniformly reduce the production cost.

By contrast, in the case where the suspension boards with circuit 2 have, e.g., the first bent portions 44 and the second bent portions 45, and the margin portions 4 each linearly extending along the vertical direction are merely formed, though not shown, spaces resulting from the first bent portions 44 and the second bent portions 45 are likely to be formed in such margin portions 4. In that case, the production yield may decrease to increase the production cost.

However, in the suspension-board-with-circuit assembly sheet 1, the margin portions 4 correspond to the portions where the suspension boards with circuit 2 are omitted so that such margin portions 4 also include the third bent portions 49 and the fourth bent portions 50 respectively corresponding to the first bent portions 44 and the second bent portions 45 of the suspension boards with circuit 2. Therefore, it is possible to form each of the suspension boards with circuit 2 into a complicated shape, and also prevent the formation of the spaces mentioned above in the margin portions 4. This achieves an improvement in production yield, and allows an easy reduction in production coast.

In the method described above, the second photoresist 22 is formed on the lower surface of the metal sheet 3. However, it is also possible to form the second photoresist 22 on the upper surface of the metal sheet 3, place the photomask 23 over the second photoresist 22, and expose the second photoresist 22 to light from thereabove via the photomask 23.

Preferably, the second photoresist 22 is formed on the lower surface of the metal sheet 3, and expose the second photoresist 22 to light from therebelow via the photomask 23. If the second photoresist 22 is provided on the upper surface of the metal sheet 3, the second photoresist 22 covers the insulating base layer 9, the conductive layer 10, and the insulating cover layer 11. Accordingly, the thickness of the second photoresist 22 may be non-uniform, and exposure accuracy may deteriorate.

On the other hand, if the second photoresist 22 is provided on the lower surface of the metal sheet 3, the second photoresist 22 can be formed to have a uniform thickness since the lower surface of the metal sheet 3 is formed flat. Therefore, the exposure steps can be performed with high exposure accuracy.

Also, in the method described above, the first exposure step and the second exposure step are successively performed. However, it is also possible to, e.g., use the photomask 23 extending long in the lateral direction, though not shown, place the photomask 23 under each of the portions of the second photoresist 22 corresponding to all the units 5 including the given unit 5A and the adjacent unit 5B in opposing relation, and simultaneously perform the exposure steps (the first exposure step and the second exposure step) via the large photomask 23 to simultaneously expose the second photoresist 22 to light.

On the other hand, in the method in which the first exposure step and the second exposure step (the individual exposure steps) shown in FIGS. 5 and 6 described above are performed in succession, each of the exposure steps is easily performed using the relatively small common photomask 23 to allow easy formation of the second etching resist 25 corresponding to the given unit 5A and the adjacent unit 5B. As a result, the production cost can be reduced.

In the description given above, each of the suspension boards with circuit 2 is formed such that the longitudinal direction thereof crosses the lateral direction. However, it is also possible to, e.g., form the suspension board with circuit 2 such that the longitudinal direction thereof extends along (is parallel with) the lateral direction, though not shown.

In this case, it is necessary to provide each of the margin portions 4 corresponding to the respective longitudinal lengths of the omitted suspension boards with circuit 2 with a relatively large area.

By contrast, in the suspension-board-with-circuit assembly sheet 1 in which the suspension boards with circuit 2 are formed such that the respective longitudinal directions thereof cross the lateral direction as shown in FIGS. 1 and 2, each of the margin portions 4 corresponding to the respective lengths of the omitted suspension boards with circuit 2 in the crossing directions can be provided with a relatively small area. Accordingly, the production yield can be further improved.

In the suspension-board-with-circuit assembly sheet 1 described above, each of the margin portions 4 is formed to be continuous, and therefore can be formed easily.

As a result, the production cost can further be easily reduced.

In the suspension-board-with-circuit assembly sheet 1 described above, the first slits 6 are formed. However, it is also possible to form the margin portions 4 without forming the first slits 6, though not shown.

Preferably, the first slits 6 are formed. If the first slits 6 are formed, and the units 5 are separated therealong, the units 5 can be easily obtained. This allows a further reduction in production cost.

The suspension-board-with-circuit assembly sheet 1 described above is formed from the lengthwise metal sheet 3 by the roll-to-toll method. However, the suspension-board-with-circuit assembly sheet 1 can also be formed from the single metal sheet 3 by a batch method, though not shown.

Preferably, the suspension-board-with-circuit assembly sheet 1 is formed using the lengthwise metal sheet 3 by the roll-to-roll method such that the units 5 are arranged in parallel along the lengthwise direction (direction of transportation) of the metal sheet 3.

In the roll-to-roll method, the units 5 can be efficiently formed, while the suspension-board-with-circuit assembly sheet 1 is transported along the lengthwise direction (direction of transportation). This allows an improvement in production efficiency.

In the method described above, the left end edge 29 (see FIG. 6(d)) of the light transmitting portions 27 of the photomask 23 in the second exposure step is disposed in overlapping relation on the left side of the right end edge 28 (see FIG. 6(c)) of the light transmitting portions 27 of the photomask 23 in the first exposure step.

However, it may be set that the right end edge 28 (see FIG. 6(c)) mentioned above and the left end edge 29 (see FIG. 6(d)) mentioned above are disposed at the same position. In that case, when lateral displacement occurs in the placement (positioning) of the photomask 23, i.e., when the left end edge 29 mentioned above is displaced rightward with respect to the right end edge 28 mentioned above, parts of the second photoresist 22 corresponding to the first joint portions 7 remain unexposed. Accordingly, by the subsequent removal by development, the discontinuous first joint portions 7 are formed disadvantageously. As a result, the laterally adjacent units 5 may be separated from each other without being reliably supported.

However, in the case where it is set that the left end edge 29 mentioned above is disposed in overlapping relation on the left side of the right end edge 29 mentioned above, even when the displacement described above occurs during the positioning, the laterally adjacent units 5 can be reliably supported without causing the discontinuous first joint portions 7 resulting from the unexposed parts of the second photoresist 22 described above as long as the displacement is within the tolerance of the lateral length of an overlapping portion. As a result, the suspension-board-with-circuit assembly sheet 1 having excellent reliability can be obtained.

In the description given above, the suspension-board-with-circuit assembly sheet 1 including the suspension boards with circuit 2 has been described as an example of the wired-circuit-board assembly sheet of the present invention. However, the wired-circuit-board assembly sheet of the present invention can also be used as a flexible-wired-circuit-board assembly sheet including flexible wired circuit boards each including the metal layer 8 as a reinforcement layer.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

What is claimed is:

1. A wired-circuit-board assembly sheet, comprising:
a plurality of wired circuit boards arranged in parallel in one direction, the wired circuit boards being regularly omitted at given intervals; and
a plurality of units defined by margin portions where the wired circuit boards are omitted.

2. The wired-circuit-board assembly sheet according to claim 1, wherein each of the wired circuit boards has a bent portion which is bent in the one direction.

3. The wired-circuit-board assembly sheet according to claim 1, wherein
the wired circuit boards are arranged in parallel such that respective longitudinal directions thereof cross the one direction, and
each of the margin portions is continuous in the longitudinal directions.

4. The wired-circuit-board assembly sheet according to claim 3, wherein each of the margin portions is formed with a slit extending along the longitudinal directions.

5. The wired-circuit-board assembly sheet according to claim 1, wherein
the wired circuit-board assembly sheet is formed into a lengthwise shape, and
the individual units are arranged in parallel along a lengthwise direction of the wired-circuit-board assembly sheet.

6. A producing method of a wired-circuit-board assembly sheet, comprising the steps of:
forming a plurality of wired circuit boards such that the wired circuit boards are arranged in parallel in one direction; and
forming a plurality of units such that the wired circuit boards are regularly omitted at given intervals, and the units are defined by margin portions where the wired circuit boards are omitted.

7. The producing method of the wired-circuit-board assembly sheet according to claim 6, wherein, in the step of forming the wired circuit boards, each of the wired circuit boards is formed to have a bent portion which is bent in the one direction.

8. The producing method of the wired-circuit-board assembly sheet according to claim 6, wherein,
in the step of forming the wired circuit boards, a metal layer made of a metal sheet, an insulating layer to be formed thereon, and a conductive layer to be formed thereon are formed, and
the step of forming the units includes:
the step of forming a photoresist on one side of the metal sheet in a thickness direction thereof;
a first exposure step of placing a photomask on one side of a portion of the photoresist corresponding to a given one of the plurality of units in a thickness direction thereof, and exposing the portion of the photoresist to light via the photomask;
a second exposure step of placing the photomask on the one side of a portion of the photoresist corresponding to the adjacent unit that is adjacent to the given unit in the thickness direction thereof, and exposing the portion of the photoresist to light via the photomask;
the step of removing an unexposed portion of the photoresist after the first exposure step and the second exposure step by development to form an etching resist; and
an etching step of etching the metal sheet exposed from the etching resist.

9. The producing method of the wired-circuit-board assembly sheet according to claim 8, wherein,
in the step of forming the wired circuit boards, the wired circuit boards are formed such that respective longitudinal directions thereof cross the one direction, and,
in the etching step, each of the margin portions is formed to be continuous in the longitudinal directions.

10. The producing method of the wired-circuit-board assembly sheet according to claim 9, wherein,
in the etching step, a slit is formed in each of the margin portions so as to extend along the longitudinal directions.

11. The producing method of the wired-circuit-board assembly sheet according to claim 8, wherein,
in the step of forming the wired circuit boards, the metal sheet having a lengthwise shape is used, and,
in the step of forming the units, the units are formed so as to be arranged in parallel along a lengthwise direction of the metal sheet.
